(19) United States
(12) Patent Application Publication
(10) Pub. No.: US 2026/0324005 A1
(43) Pub. Date: Oct. 15, 2026

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Hengyuan LEE, Hsinchu County (TW); Xinyu BAO, Fremont, CA (US)

(73) Assignee: TAIWAN SEMICONDUCTOR MANUFACTURING COMPANY, LTD., Hsinchu (TW)

(21) Appl. No.: 19/179,335

(22) Filed: Apr. 15, 2025

(51) Int. Cl. H10D 30/67; H01L 23/528; H10D 30/01; H10D 62/10; H10D 86/00

(52) U.S. Cl. CPC H10D 30/6757; H10D 30/0314; H10D 30/0316; H10D 30/6731; H10D 30/6732; H10D 30/6736; H10D 30/6737; H10D 30/6755; H10D 86/215; H10W 20/435; H10D 62/124

(57) ABSTRACT

A method includes forming a first transistor over a substrate, including forming a gate electrode over the substrate. A gate dielectric layer is formed to cover the gate electrode. A p-type channel layer made of oxide semiconducting materials is formed over the gate dielectric layer. A conductive interfacial layer is formed over the p-type channel layer. The conductive interfacial layer is made of a conductive oxide material, and the conductive interfacial layer and the p-type channel layer comprise a same metal. A first source/drain electrode and a second source/drain electrode are formed on opposite sides of the p-type channel layer. The conductive interfacial layer separates the first source/drain electrode from the p-type channel layer. The first source/drain electrode is made of aluminum-containing materials.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that may be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1I illustrate cross-sectional views of intermediate stages in the formation of the integrated circuit structure (or the semiconductor device) in accordance with some embodiments of the present disclosure.

FIG. 2 is a cross-sectional view of an integrated circuit structure (or a semiconductor device) in accordance with some embodiments of the present disclosure.

FIG. 3 is a cross-sectional view of an integrated circuit structure (or a semiconductor device) in accordance with some embodiments of the present disclosure.

FIGS. 4A-4E illustrate exemplary cross-sectional views of various stages for manufacturing an integrated circuit structure (or a semiconductor device) according to some other embodiments of the present disclosure.

FIGS. 5A-5G illustrate exemplary cross-sectional views of various stages for manufacturing an integrated circuit structure (or a semiconductor device) according to some other embodiments of the present disclosure.

FIGS. 6A-6E illustrate exemplary cross-sectional views of various stages for manufacturing an integrated circuit structure (or a semiconductor device) according to some other embodiments of the present disclosure.

FIG. 7 is a plot of on and off currents under different gate lengths of TFTs before and after the annealing process.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “conductive” refers to an electrically conductive structure, layer, and/or region. As used herein, source/drain region(s) may refer to a source or a drain, individually or collectively dependent upon the context. As used herein, the term “p-type materials” refers to materials have an excess of “holes” where an electron could exist, and the term “n-type materials” refers to materials have an excess of electrons.

The present disclosure relates to transistors that are disposed within a back-end-of line (BEOL) metal interconnect of an integrated chip. The BEOL metal interconnect includes a plurality of vias and conductive lines that provide interconnects within inter-metal dielectric (IMD) layers. The transistors in the BEOL metal interconnect may be thin film transistors (TFTs). In some embodiments, the TFTs are p-type electrical conductivity, and have distinct Ion/Ioff characteristics after high-temperature annealing processes.

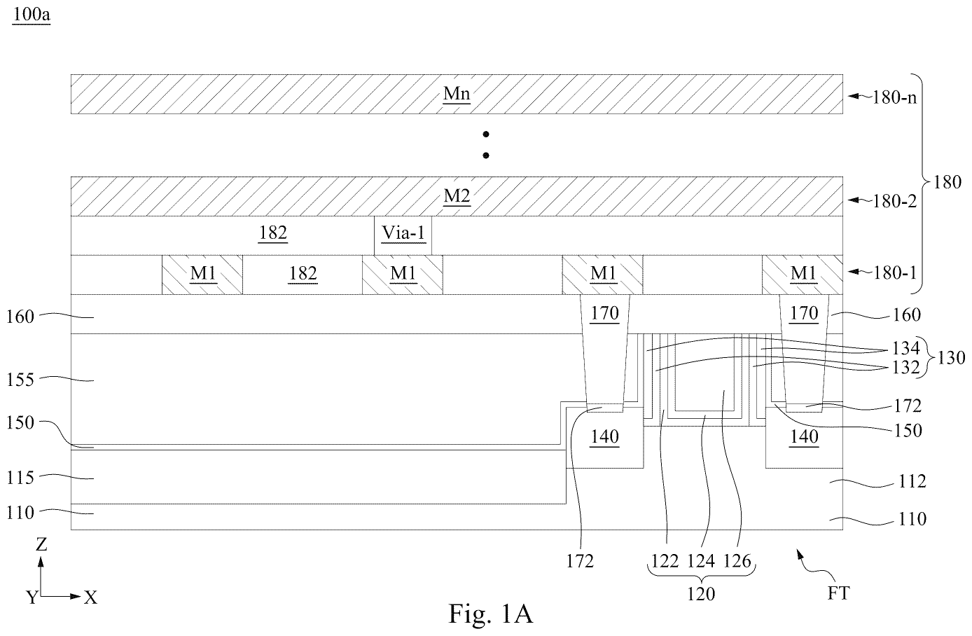

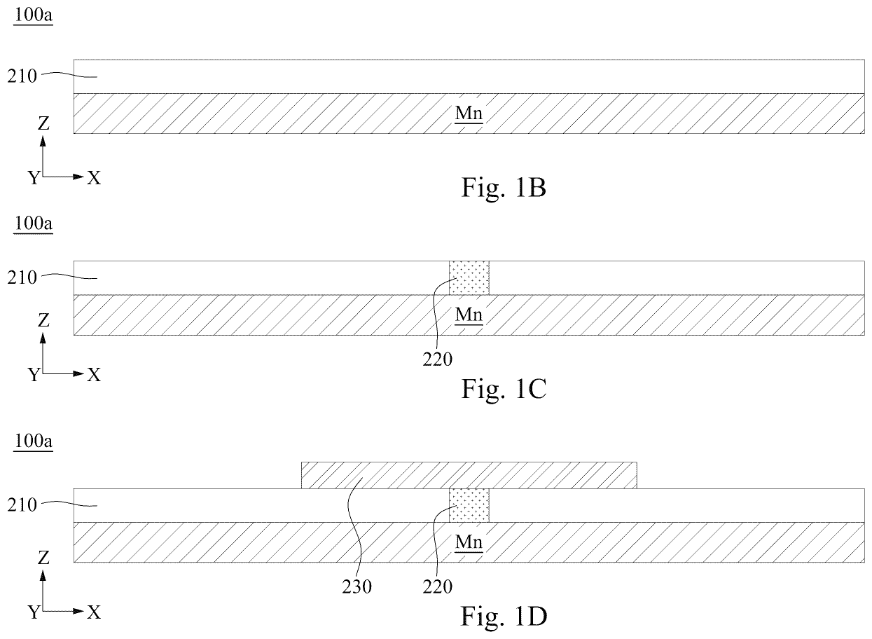

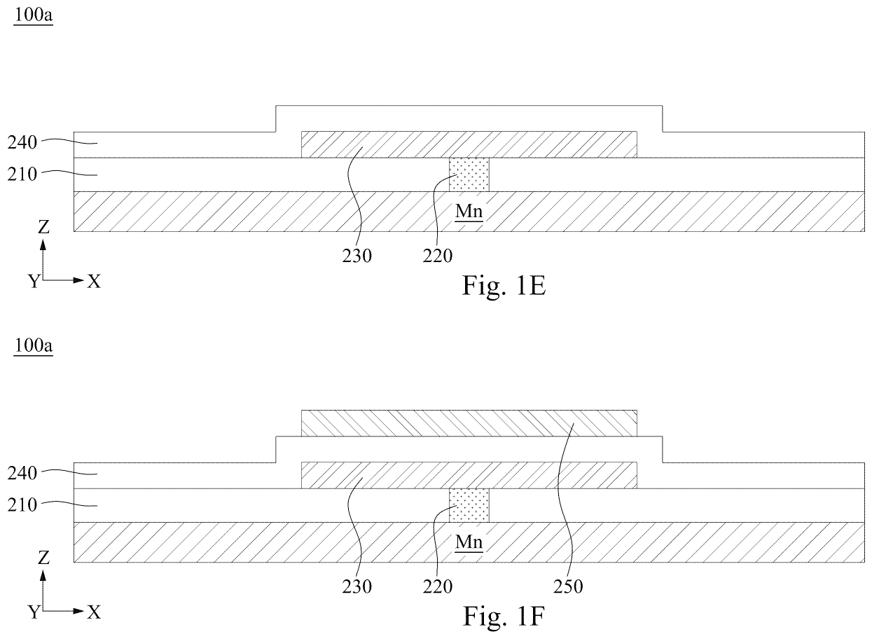

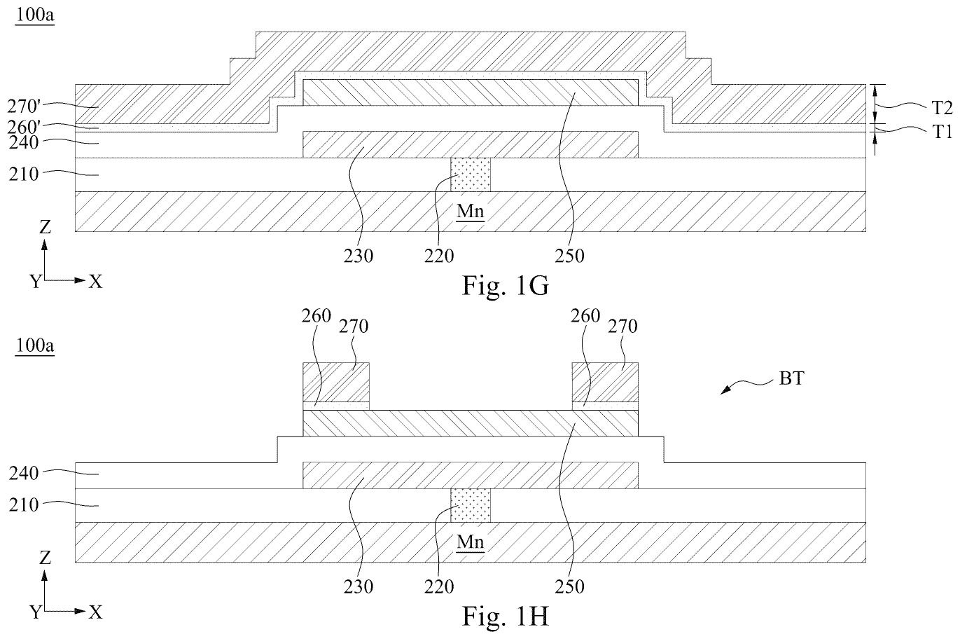

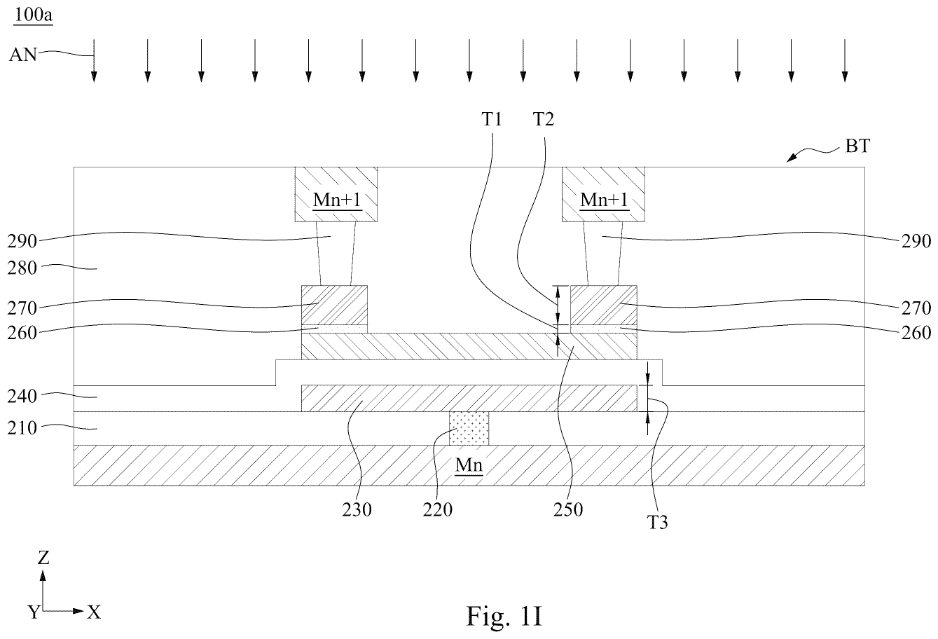

FIGS. 1A-1I illustrate cross-sectional views of intermediate stages in the formation of the integrated circuit structure (or the semiconductor device) 100a in accordance with some embodiments of the present disclosure. The formed devices include front-end-of line (FEOL) transistors (such as planar FETs, FinFETs, and/or GAA FETs) and BEOL transistors (such as TFTs) in accordance with some exemplary embodiments. Throughout the various views and illustrative embodiments, like reference numbers are used to designate like elements. It is understood that additional operations can be provided before, during, and after the processes shown by FIGS. 1A-1I, and some of the operations described below can be replaced or eliminated, for additional embodiments of the method. The order of the operations/processes may be interchangeable.

As shown in FIG. 1A, a substrate 110 is provided. In some embodiments, the substrate 110 is made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide, indium gallium arsenide InGaAs, indium arsenide, indium phosphide, indium antimonide, gallium arsenic phosphide, or gallium indium phosphide), or the like. Further, the substrate 110 may include an epitaxial layer (epi-layer), which may be strained for performance enhancement, and/or may include a silicon-on-insulator (SOI) structure.

A least one device is formed over the substrate 110. For example, a transistor FT formed over substrate 110. One or more semiconductor fin 112 of the transistor FT is formed on the substrate 110. The semiconductor fin 112 may be N-type or P-type. The semiconductor fin 112 may be formed by performing an etching process to the substrate 110. Isolation structures 115, such as shallow trench isolations (STI), are then formed on the substrate 110 and surround a bottom portion of the semiconductor fin 112.

The transistor FT further includes a gate structure 120 over the semiconductor fin 112. The gate structure 120 includes a gate dielectric layer 122 and a gate electrode over the gate dielectric layer 122. The gate electrode may include a work function metal layer 124 formed over the gate dielectric layer 122 and a fill metal 126 formed over the work function metal layer 124. The gate dielectric layer 122 includes an interfacial layer (e.g., silicon oxide layer) and a high-k gate dielectric layer over the interfacial layer. In some embodiments, the interfacial layer of the gate dielectric layer 122 may include a dielectric material such as silicon oxide (SiO₂), HfSiO, or silicon oxynitride (SiON). The high-k dielectric layer of the gate dielectric layer 122 may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The work function metal layer 124 and/or fill metal 126 used within gate structure 120 may include a metal, metal alloy, or metal silicide. The work function metal layer 124 may include titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), titanium nitride (TiN), tungsten nitride (WN), tungsten (W), ruthenium (Ru), palladium (Pd), platinum (Pt), cobalt (Co), nickel (Ni), aluminides, conductive metal oxides, and/or other suitable materials. In some embodiments, the fill metal 126 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

The transistor FT further includes gate spacers 130 at least on opposite sidewalls of the gate structure 120. In some embodiments, the gate spacers 130 each includes multiple layers, such as a first spacer layer 132 and a second spacer layer 134 formed over the first spacer layer 132. The first and second spacer layers 132 and 134 each are made of a suitable material such as silicon oxide, silicon nitride, silicon carbide, silicon oxynitride, SiCN, silicon oxycarbide, SiOCN, and/or combinations thereof.

The transistor FT further includes source/drain epitaxial structures 140 on opposite sides of the gate structure 120. In some embodiments, formation of the source/drain epitaxial structures 140 includes recessing source/drain regions of the semiconductor fin 112, followed by epitaxially growing semiconductor materials in the recessed source/drain regions of the semiconductor fin 112. In some embodiments, the source/drain epitaxial structures 140 include Ge, Si, GaAs, AlGaAs, SiGe, GaAsP, SiP, or other suitable material.

It is noted that although the transistor FT is a FinFET in FIG. 1A, the transistor T may be a planar FET, a horizontal gate-all-around (HGAA) FET, a vertical gate-all-around (VGAA) FET, or other types of transistors. Since the transistor FT is formed in an FEOL of the manufacturing process, the transistor FT can be regarded as an FEOL transistor. Further, the (FEOL) devices formed over the substrate 110 may be capacitors, resistors, diodes, photo-diodes, fuses, and the like. The functions of the devices may include memory structures, processing structures, sensors, amplifiers, power distribution, input/output circuitry, or the like. One of ordinary skill in the art will appreciate that the above examples are provided for illustrative purposes only to further explain applications of some illustrative embodiments and are not meant to limit the disclosure in any manner. Other circuitry may be used as appropriate for a given application.

A contact etch stop layer (CESL) 150, a first interlayer dielectric (ILD) layer 155, and a second ILD layer 160 are formed over the substrate 110. The CESL 150 is formed on the isolation structure 115, the source/drain epitaxial structures 140, and surrounds the gate structure 120. The first ILD layer 155 is formed on the CESL 150, and the second ILD layer 160 is formed on the first ILD layer 155 and the gate structure 120. In some embodiments, the CESL 150 includes a silicon nitride layer, a silicon oxynitride layer, and/or other suitable materials having a different etch selectivity than the first ILD layer 155 and the second ILD layer 160. In some embodiments, the first ILD layer 155 and the second ILD layer 160 each includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 150.

A plurality of source/drain contacts 170 are formed extending through the first ILD layer 155 and the second ILD layer 160 and are electrically connected to the source/drain epitaxial structures 140. Formation of the source/drain contacts 170 includes, by way of example and not limitation, performing one or more etching processes to form contact openings extending though the first ILD layer 155, the second ILD layer 160, and the CESL 150 to expose the source/drain epitaxial structures 140, depositing one or more metal materials overfilling the contact openings, and then performing a CMP process to remove excessive metal materials outside the contact openings. In some embodiments, the source/drain contacts 170 are made of metal, such as W, Co, Ru, Al, Cu, or other suitable materials. In some embodiments, barrier layers are formed in the contact openings before the formation of the source/drain contacts 170. The barrier layers may be made of TiN, TaN, or combinations thereof.

In some embodiments, metal alloy layers 172 are respectively formed above the source/drain epitaxial structures 140 prior to forming the source/drain contacts 170. The metal alloy layers 172, which may be silicide layers, are respectively formed in the trenches and over the exposed source/drain epitaxial structures 140 by a self-aligned silicide (salicide) process. The silicide layer may include a material selected from titanium silicide, cobalt silicide, nickel silicide, platinum silicide, nickel platinum silicide, erbium silicide, palladium silicide, combinations thereof, or other suitable materials. In some embodiments, the metal alloy layers 172 may include germanium. In some embodiments, the structures deposited from the substrate 110 to the second ILD layer 160 (i.e., the transistor FT and the source/drain contacts 170) are referred to be front-end of line (FEOL) and middle-end of line (MEOL) structures.

A multilevel interconnection structure 180 is formed above the second ILD layer 160 and the source/drain contacts 170. The multilevel interconnection structure 180 includes a plurality of conductive layers that provide interconnections (wiring) between the various microelectronic elements, and between conductive layers themselves. It is understood that the number of conductive layers may vary depending on the design of the particular semiconductor device. In FIG. 1A, the conductive layers include n conductive layers with a bottommost conductive layer 180-1, an upper conductive layer 180-n, and conductive layers 180-2, . . . between the bottommost conductive layer 180-1 and the upper conductive layer 180-n. In the BEOL scheme illustrated in FIG. 1A, various interconnect levels have similar features. However, it is understood that other embodiments may utilize alternate integration schemes wherein the various interconnect levels may use different features.

The conductive layers 180-1 to 180-n and the IMD layers 182 may be formed in an integrated process such as a damascene process or lithography/plasma etching process. The bottommost conductive layer 180-1 may include the conductive lines M1 that are coupled to the source/drain contacts 170 for connecting to the devices formed in the substrate 110. The multilevel interconnection structure 180 may further include various metal vias (e.g., the metal via Via-1) disposed within the IMD layers 182 for connecting the conductive lines M1, M2, . . . , Mn of adjacent conductive layers 180-1 to 180-n.

The conductive lines M1, M2, . . . , Mn may be formed of a conductive material such as aluminum, aluminum/silicon/copper alloy, titanium, titanium nitride, tungsten, polysilicon, metal silicide, or combinations thereof. Alternatively, the conductive lines M1, M2, . . . , Mn may be formed of copper, copper alloy, titanium, titanium nitride, tantalum, tantalum nitride, tungsten, polysilicon, metal silicide, or combinations thereof. The adjacent conductive layers may include conductive lines extending in different directions. For example, the conductive lines in the odd layers (e.g., the conductive lines M1) may extend in the Y direction, and the conductive lines in the even layers (e.g., the conductive lines M2 and Mn) may extend in the X direction, or vice versa.

The conductive layers 180-1 to 180-n may be insulated from each other by inter-metal dielectric (IMD) layers 182. The IMD layers 182 may include a material of a low dielectric constant or low k value (low-k). In some embodiments, the IMD layers 182 at various levels of the multilevel interconnection structure 180 may be formed of different dielectric materials. It is has been observed that IMD layers 182 with low-K (LK), extreme low-K (ELK), and/or extra low-k (XLK) materials may enhance circuit performance. The LK, ELK, and/or XLK dielectric materials may include silicon nitride, silicon oxynitride, spin-on glass (SOG), undoped silicate glass (USG), fluorinated silica glass (FSG), carbon doped silicon oxide (e.g., SiCOH), carbon-containing material, Black Diamond, Xerogel, Aerogel, amorphous fluorinated carbon, Parylene, BCB (bis-benzocyclobutenes), Flare, SiLK (Dow Chemical, Midland, Mich.), polyimide, other proper porous polymeric materials, other suitable dielectric materials, and/or combinations thereof. The IMD layers 182 may be formed by a technique including spin-on, CVD, PVD, or atomic layer deposition (ALD).

Although an example electronic device (e.g., the transistor FT) and example interconnect structures making connections to the electronic device are described, it is understood that one of ordinary skill in the art will appreciate that the above examples are provided for illustrative purposes only to further explain applications of the present embodiments, and are not meant to limit the present embodiments in any manner.

Reference is made to FIG. 1B. For clarity, the structures under the conductive line Mn are omitted in FIGS. 1B-1I. The conductive line Mn is embedded in the IMD layer 182 (see FIG. 1A). A dielectric layer 210 is formed over the IMD layer 182 and the conductive line Mn. In some embodiments, the dielectric layer 210 may include one or more dielectric materials such as Si₃N₄, SiON, SiC, SiCN, or combinations thereof in various embodiments. The dielectric layer 210 may be formed by any suitable deposition process, such as spin coating, physical vapor deposition (PVD), chemical vapor deposition (CVD), the like, or a combination thereof.

Reference is made to FIG. 1C. At least one conductive via 220 is formed in the dielectric layer 210. For example, the dielectric layer 210 is patterned to form a via opening therein, and a conductive material is filled in the via opening to form the conductive via 220. In some embodiments, the conductive via 220 is made of metal, such as W, Co, Ru, Al, Cu, or other suitable materials. In some embodiments, barrier layers are formed in the via openings before the formation of the conductive via 220. The barrier layers may be made of TiN, TaN, or combinations thereof.

Reference is made to FIG. 1D. A gate electrode 230 is formed over the dielectric layer 210 and the conductive via 220. In some embodiments, the gate electrode 230 is in contact with the conductive via 220 such that the gate electrode 230 is electrically connected to the conductive line Mn through the conductive via 220. For example, a conductive layer may be deposited over the dielectric layer 210 and the conductive via 220, and a patterning process is performed to the conductive layer, such that the conductive layer is patterned to form the gate electrode 230. In some embodiments, the conductive layer (and thus the gate electrode 230) is made of semiconductor materials, e.g., silicon, and/or metal containing materials, e.g., Cu, Al, W, Co, Ru, TiN, TaN, Ru, Mo, Al, combinations thereof, or the like. The conductive layer may be deposited by any suitable method, e.g., CVD, PECVD, physical vapor deposition (PVD), ALD, PEALD, electrochemical plating (ECP), electroless plating and/or the like.

Reference is made to FIG. 1E. A gate dielectric layer 240 is deposited over the dielectric layer 210 and covers the gate electrode 230. In some embodiments, the gate dielectric layer 240 includes one or more high-k dielectric layers. High-k gate dielectrics, as used and described herein, include dielectric materials having a high dielectric constant, for example, greater than that of thermal silicon oxide (about 3.9). The high-k dielectric material of the gate dielectric layer 240 may include, by way of example and not limitation, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (La₂O₃), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

Reference is made to FIG. 1F. A channel layer 250 is formed over the gate dielectric layer 240. For example, an oxide semiconducting layer is deposited over the gate dielectric layer 240, and a patterning process is performed to the oxide semiconducting layer, such that the oxide semiconducting layer is patterned to form the channel layer 250. In some embodiments, the oxide semiconducting layer (and thus the channel layer 250) is made of p-type tin monoxide (SnO). SnO is one of promising p-type channel oxide materials. The thin film SnO has quite high mobility values. SnO is a p-type oxide material and is a transparent semiconducting oxide (TSO) material. The oxide semiconducting layer may be deposited by any suitable method, e.g., CVD, PECVD, physical vapor deposition (PVD), ALD, PEALD, electrochemical plating (ECP), electroless plating and/or the like.

Reference is made to FIG. 1G. A first conductive layer 260′ is deposited over the channel layer 250 and the gate dielectric layer 240, and a second conductive layer 270′ is deposited over the first conductive layer 260′. The first conductive layer 260′ and the second conductive layer 270′ may be deposited by any suitable method, e.g., CVD, PECVD, physical vapor deposition (PVD), ALD, PEALD, electrochemical plating (ECP), electroless plating and/or the like.

In some embodiments, the first conductive layer 260′ is made of conductive oxide. For example, the first conductive layer 260′ is made of indium tin oxide (ITO). The first conductive layer 260′ (and thus the following formed conductive interfacial layers 260 in FIG. 1H) and the channel layer 250 include the same metal (i.e., Sn), and the Sn atomic percentage in the channel layer 250 is higher than the Sn atomic percentage in the first conductive layer 260′.

In some embodiments, the second conductive layer 270′ (and thus the following formed source/drain electrodes 270 in FIG. 1H) is made of aluminum-containing conductive materials. For example, the second conductive layer 270′ is made of pure or substantially pure aluminum (e.g., the Al atomic percentage is greater than about 95%). In some other embodiments, the second conductive layer 270′ is made of aluminum alloy, in which the Al atomic percentage is higher than about 50%. For example, the aluminum alloy includes a first metal (aluminum) and a second metal (e.g., copper, magnesium, silicon, manganese, tin, nickel, zinc, combinations thereof, or other suitable metals). In some embodiments, a metal percentage of the second conductive layer 270′ is higher than about 90%. In some embodiments, the second conductive layer 270′ is substantially free of oxygen and/or oxide (e.g., lower than about 5% of oxygen atomic percentage). In some embodiments, the first conductive layer 260′ and the second conductive layer 270′ includes different metals. For example, the first conductive layer 260′ is substantially free of aluminum, e.g., an aluminum atomic percentage of the first conductive layer 260′ is lower than about 1%. In some embodiments, the second conductive layer 270′ has an electrical conductivity higher than an electrical conductivity of the first conductive layer 260′. In some embodiments, a thickness T1 of the first conductive layer 260′ is less than a thickness T2 of the second conductive layer 270′.

Reference is made to FIGS. 1G and 1H. The second conductive layer 270′ is patterned by one or more etching processes to form source/drain electrodes 270 over opposite sides of the channel layer 250. Subsequently, the first conductive layer 260′ is patterned by one or more etching processes to form conductive interfacial layers 260 between the channel layer 250 and respective source/drain electrodes 270. Example etching processes include, but are not limited to, dry etching, wet etching, reactive ion etching (RIE), and/or other suitable processes. Therefore, a (BEOL) transistor BT is formed over the conductive line Mn and the transistor FT (see FIG. 1A).

Reference is made to FIGS. 1H and 1I. An IMD layer 280 is formed to cover the structure in FIG. 1H. In some embodiments, the IMD layer 280 is made of an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon dioxide (SiO₂). In some embodiments, ELK dielectric material is deposited by a plasma enhanced chemical vapor deposition (PECVD) process or by a spin coating process.

Conductive vias 290 and conductive lines Mn+1 are formed in the IMD layer 280. In some embodiments, appropriate photolithography and etching techniques (e.g., anisotropic RIE employing fluorocarbon chemistry) may be used to pattern the IMD layer 280 to form openings for vias and lines. Openings for conductive vias 290 are vertical holes extending through the IMD layer 280 into the source/drain electrodes 270.

Several conductive materials may be deposited to fill the openings and trenches forming the conductive vias 290 and conductive lines Mn+1. In some embodiments, the conductive materials include, for example, TaN, TiN, W, Al, polysilicon, Ru, Co, Cu, combinations thereof, or the like. The openings may be first lined with a conductive diffusion barrier material and then completely filled with a conductive fill material deposited over the conductive diffusion barrier liner. In some embodiments, a thin conductive seed layer may be deposited over the conductive diffusion barrier liner to help initiate an electrochemical plating (ECP) deposition step that completely fills the openings with a conductive fill material. The conductive materials used in forming the conductive vias 290 and conductive lines Mn+1 may be deposited by any suitable method, for example, CVD, PECVD, PVD, ALD, PEALD, ECP, electroless plating and the like. Although not depicted herein, additional dielectric layers, BEOL via structures, and BEOL conductive lines may be formed over the conductive lines Mn+1 and the IMD layer 182 as a part of the multilevel interconnection structure 180.

After the formation of the transistor BT, an annealing process (or a thermal process or a heating process) AN is performed to the structure of FIG. 1I. In some embodiments, the annealing process AN may be performed at a temperature equal to or higher than about 400° C. (may be in a range of about 250° C. and about 450° C. in some embodiments). The annealing process AN may degrade the electrical performance of the device in some scenarios. However, due to the conductive interfacial layers 260 formed between the channel layer 250 and the source/drain electrodes 270, the elements or atoms in the conductive interfacial layers 260 and/or in the source/drain electrodes 270 do not diffuse into the channel layer 250 during the annealing process AN. As such, the channel layer 250 maintains its electrical performance after the annealing process AN.

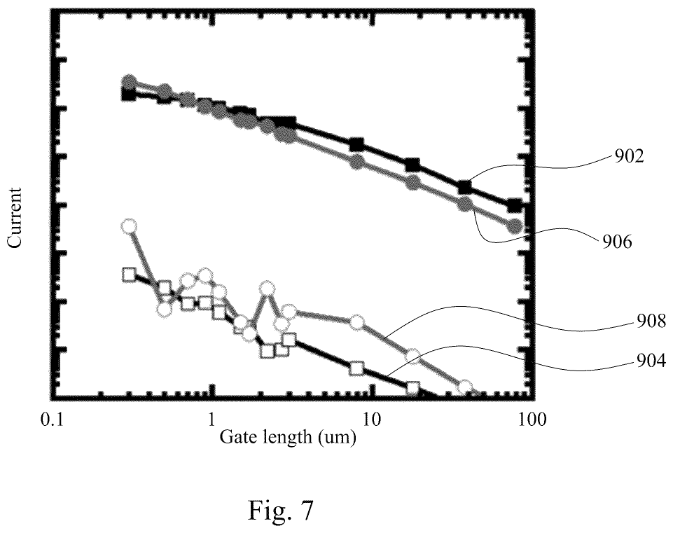

FIG. 7 is a plot of on and off currents under different gate lengths of TFTs (e.g., the transistor BT of FIG. 1I) before and after the annealing process. Line 902 represents the on currents (Iₒₙ) of the TFTs before the annealing process, line 904 represents the off currents (I_{off}) of the TFTs before the annealing process, line 906 represents the on currents (Iₒₙ) of the TFTs after the annealing process, and line 908 represents the off currents (I_{off}) of the TFTs after the annealing process. As shown in FIG. 7, the TFTs still have distinguished on and off current ratio (e.g., Iₒₙ/I_{off} is greater than about 10², and may be lower than about 10¹⁰) after the annealing process. Further, the difference between the on currents before and after the annealing process is smaller than about 10 times, and the difference between the off currents before and after the annealing process is smaller than about 100 times, further smaller than about 10 times. The results indicate that the electrical performance of the TFTs are not degraded after the annealing process, and the combinations of the channel layer, the conductive interfacial layers, and the source/drain electrodes have a high thermal stability.

In FIG. 1I, the transistor BT is a p-type thin film transistor (TFT) and includes the gate electrode 230, the gate dielectric layer 240, the channel layer 250, the conductive interfacial layers 260, and the source/drain electrodes 270. The gate dielectric layer 240 covers the gate electrode 230, the channel layer 250 is over the gate dielectric layer 240 and the gate electrode 230. The source/drain electrodes 270 are on opposite sides of the channel layer 250, and the conductive interfacial layers 260 are between the channel layer 250 and the respective source/drain electrodes 270. Therefore, the conductive interfacial layers 260 separate the source/drain electrodes 270 from the channel layer 250. The materials in the conductive interfacial layers 260 do not diffuse into the channel layer 250, and the conductive interfacial layers 260 further prevent the materials in the source/drain electrodes 270 from diffusing into the channel layer 250 during the annealing process AN. Therefore, the channel layer 250 remains good electrical performance after the annealing process AN. In some embodiments, the conductive lines Mn and Mn+1 extend in different directions. For example, the conductive line Mn extends in the X direction, and the conductive lines Mn+1 extend in the Y direction. Further, the conductive lines Mn+1 may be thicker than the conductive line Mn in the Z direction.

In some embodiments, the conductive interfacial layers 260 each has the thickness T1, and the source/drain electrodes 270 each has the thickness T2 greater than the thickness T1. With such configuration, the conductive interfacial layers 260 have good electrical conductivity while are thick enough to prevent the material diffusion during the annealing process AN. In some embodiments, the channel layer 250 has a thickness T3 greater than the thickness T1 of the conductive interfacial layers 260. In some embodiments, the thickness T1 of the conductive interfacial layer 260 is in a range of about 1 nm and about 5 um. In some embodiments, the thickness T2 of the source/drain electrodes 270 is in a range of about 1 nm and about 5 um. In some embodiments, the thickness T3 of the channel layer 250 is in a range of about 1 nm and about 5 um.

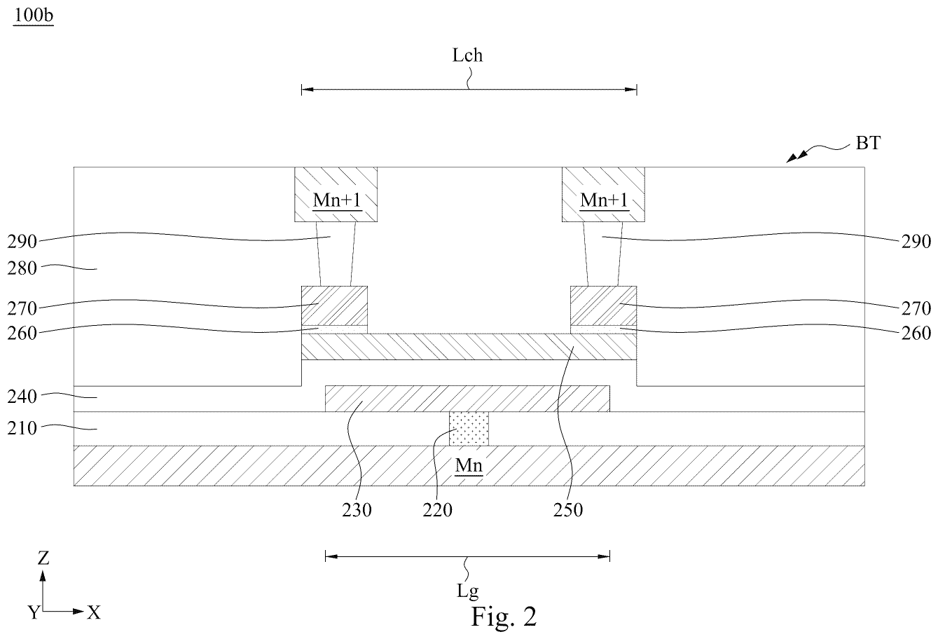

FIG. 2 is a cross-sectional view of an integrated circuit structure (or a semiconductor device) 100b in accordance with some embodiments of the present disclosure. The difference between the semiconductor device 100b in FIG. 2 and the semiconductor device 100a in FIG. 1I pertains to the configuration of the gate electrode 230. In FIG. 2, a channel length Lch of channel layer 250 is greater than a gate length Lg of the gate electrode 230. Other features of the semiconductor device 100b are similar to those of the semiconductor device 100a shown in FIG. 1I, and therefore, a description in this regard will not be provided hereinafter.

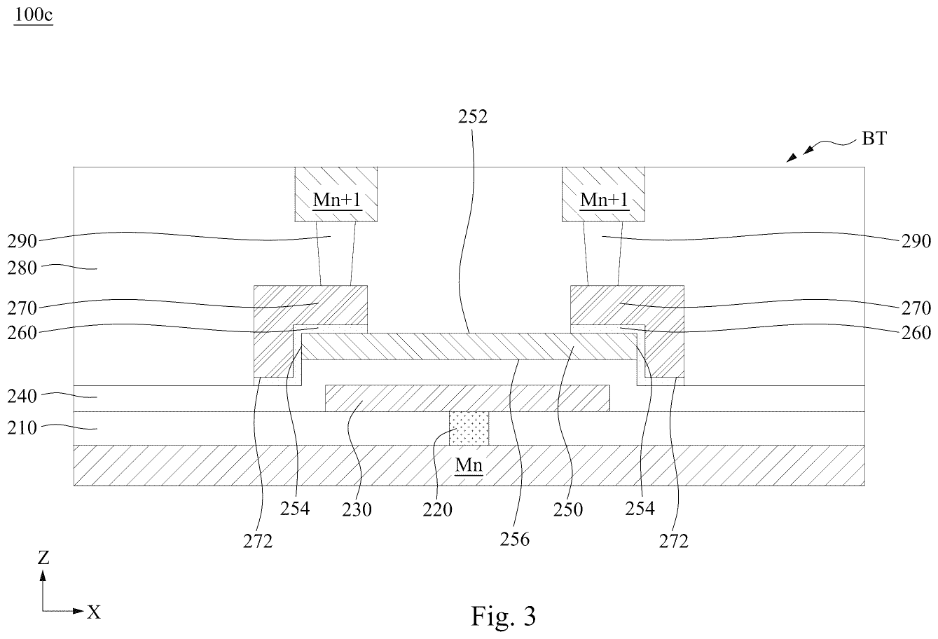

FIG. 3 is a cross-sectional view of an integrated circuit structure (or a semiconductor device) 100c in accordance with some embodiments of the present disclosure. The difference between the semiconductor device 100c in FIG. 3 and the semiconductor device 100b in FIG. 2 pertains to the configuration of the source/drain electrodes 270 and the conductive interfacial layers 260. In FIG. 3, the conductive interfacial layers 260 are not only in contact with the top surface 252 of the channel layer 250, but also in contact with the opposite sidewalls 254 of the channel layer 250. Further, the source/drain electrodes 270 extend from the top surface 252 of the channel layer 250 to the respective sidewalls 254 of the channel layer 250. Therefore, the conductive interfacial layers 260 further separate (the sidewalls 254 of) the channel layer 250 from the source/drain electrodes 270. In some embodiments, the conductive interfacial layers 260 are further in contact with the gate dielectric layer 240, and bottom surfaces 272 of the source/drain electrodes 270 are lower than a bottom surface 256 of the channel layer 250. With such configuration, the size of the source/drain electrodes 270 is increased, and the electrical resistance of the source/drain electrodes 270 is lowered. Further, the contact area between the conductive interfacial layers 260 and the channel layer 250 is increased, reducing the contact resistance therebetween. As shown in FIG. 3, the channel layer 250 is in contact with a portion of each of the conductive interfacial layer 260, and the gate dielectric layer 240 is in contact with another portion of each of the conductive interfacial layer. Other features of the semiconductor device 100c are similar to those of the semiconductor device 100b shown in FIG. 2, and therefore, a description in this regard will not be provided hereinafter.

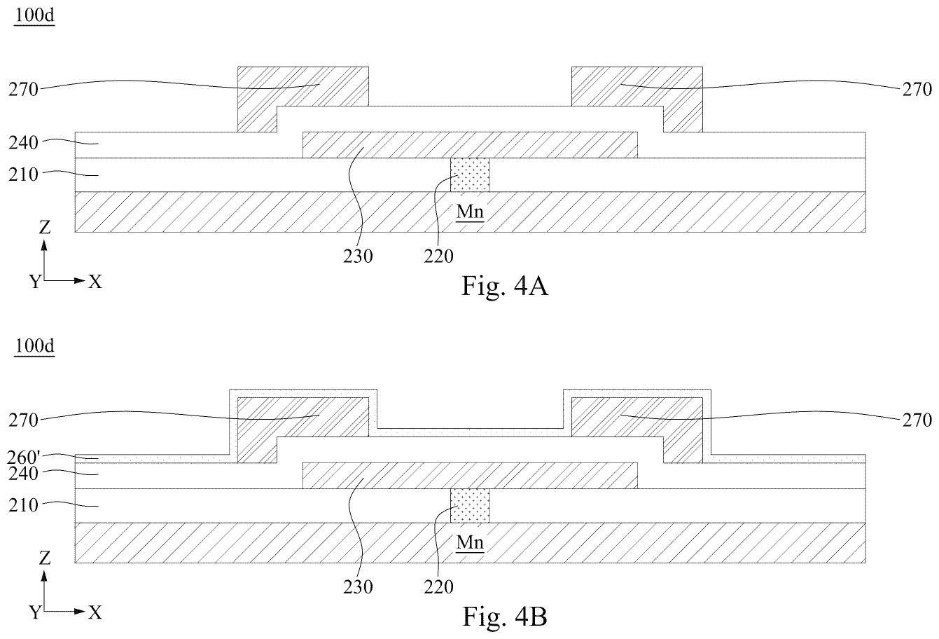

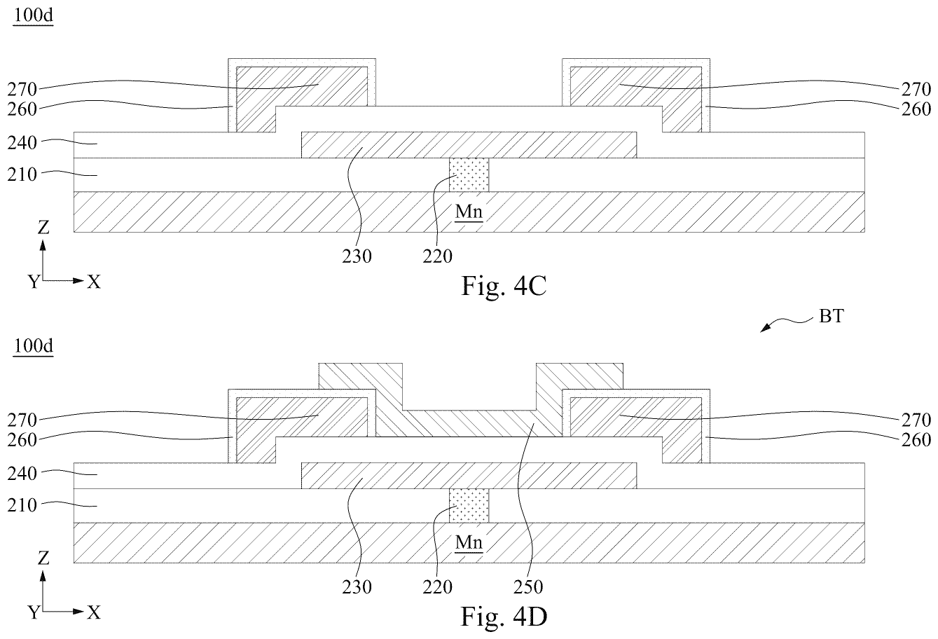

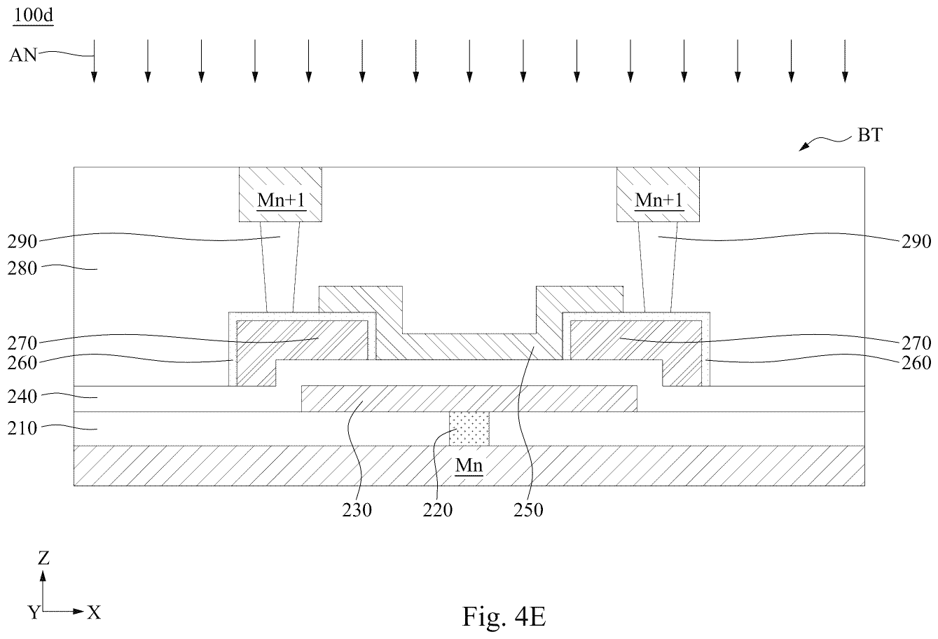

FIGS. 4A-4E illustrate exemplary cross-sectional views of various stages for manufacturing an integrated circuit structure (or a semiconductor device) 100d according to some other embodiments of the present disclosure. It is understood that additional operations can be provided before, during, and after processes shown by FIGS. 4A-4E, and some of the operations described below can be replaced or eliminated, for additional embodiments of the method. The order of the operations/processes may be interchangeable. The same or similar configurations, materials, processes and/or operation as described with FIGS. 1A-1I may be employed in the following embodiments, and the detailed explanation may be omitted.

After the structure as shown in FIG. 1E is formed, source/drain electrodes 270 are formed over the gate dielectric layer 240 as shown in FIG. 4A. For example, a conductive layer is deposited over the gate dielectric layer 240 and is then patterned to from the source/drain electrodes 270. Materials, configurations, dimensions, processes and/or operations regarding the source/drain electrodes 270 are similar to or the same as the source/drain electrodes 270 described in FIG. 1I.

Reference is made to FIG. 4B. A conductive layer 260′ is deposited over the source/drain electrodes 270 and the gate dielectric layer 240. Materials, configurations, dimensions, processes and/or operations regarding the conductive layer 260′ are similar to or the same as the first conductive layer 260′ described in FIG. 1G.

Reference is made to FIGS. 4B and 4C. The conductive layer 260′ is then patterned to be conductive interfacial layers 260 covering the source/drain electrodes 270, respectively. For example, as shown in FIG. 4C, the conductive interfacial layers 260 are in contact with outer surfaces of the source/drain electrodes 270 to separate the source/drain electrodes 270 from the following formed channel layer 250 (see FIG. 4D).

Reference is made to FIG. 4D. A channel layer 250 is formed over the conductive interfacial layers 260 and the gate dielectric layer 240. Materials, configurations, dimensions, processes and/or operations regarding the channel layer 250 are similar to or the same as the channel layer 250 described in FIG. 1F. In some embodiments, portions of the conductive interfacial layers 260 are uncovered by the channel layer 250. However, the channel layer 250 is still separated from the source/drain electrodes 270 by the conductive interfacial layers 260. The transistor BT is formed in FIG. 4D.

Reference is made to FIG. 4E. The structure of FIG. 4D undergoes the process shown in FIG. 1I. That is, an IMD layer 280 is formed to cover the structure in FIG. 4D, conductive vias 290 and conductive lines Mn+1 are formed in the IMD layer 280, and an annealing process AN is performed to the device. Materials, configurations, dimensions, processes and/or operations regarding the IMD layer 280 are similar to or the same as the IMD layer 280 described in FIG. 1I, materials, configurations, dimensions, processes and/or operations regarding the conductive vias 290 are similar to or the same as the conductive vias 290 described in FIG. 1I, and materials, configurations, dimensions, processes and/or operations regarding the conductive lines Mn+1 are similar to or the same as the conductive lines Mn+1 described in FIG. 1I.

As such, the transistor BT is a p-type thin film transistor (TFT) and includes the gate electrode 230, the gate dielectric layer 240, the channel layer 250, the conductive interfacial layers 260, and the source/drain electrodes 270. The gate dielectric layer 240 covers the gate electrode 230, and the channel layer 250 is over the gate dielectric layer 240 and the gate electrode 230. The source/drain electrodes 270 are between the channel layer 250 and the gate electrode 230. Portions of the conductive interfacial layers 260 are between the channel layer 250 and the respective source/drain electrodes 270. Stated another way, the source/drain electrodes 270 are on opposite sides of the gate electrode 230, the conductive interfacial layers 260 are over the source/drain electrodes 270, respectively, and the channel layer 250 is over the conductive interfacial layers 260. In some embodiments, the conductive vias 290 is in contact with the conductive interfacial layers 260. In some embodiments, the conductive interfacial layers 260 and the gate dielectric layer 240 together surround the respective source/drain electrodes 270.

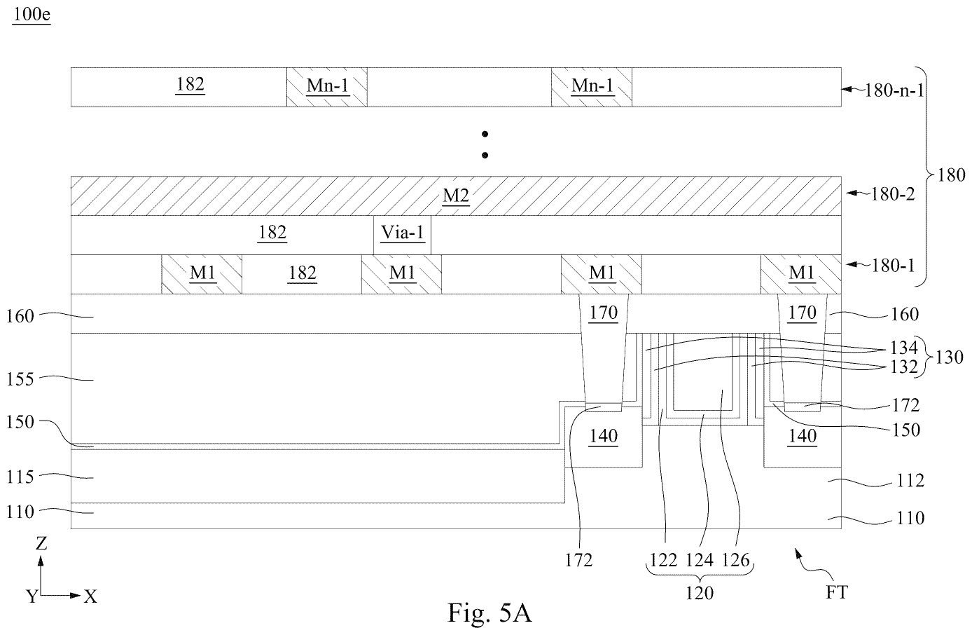

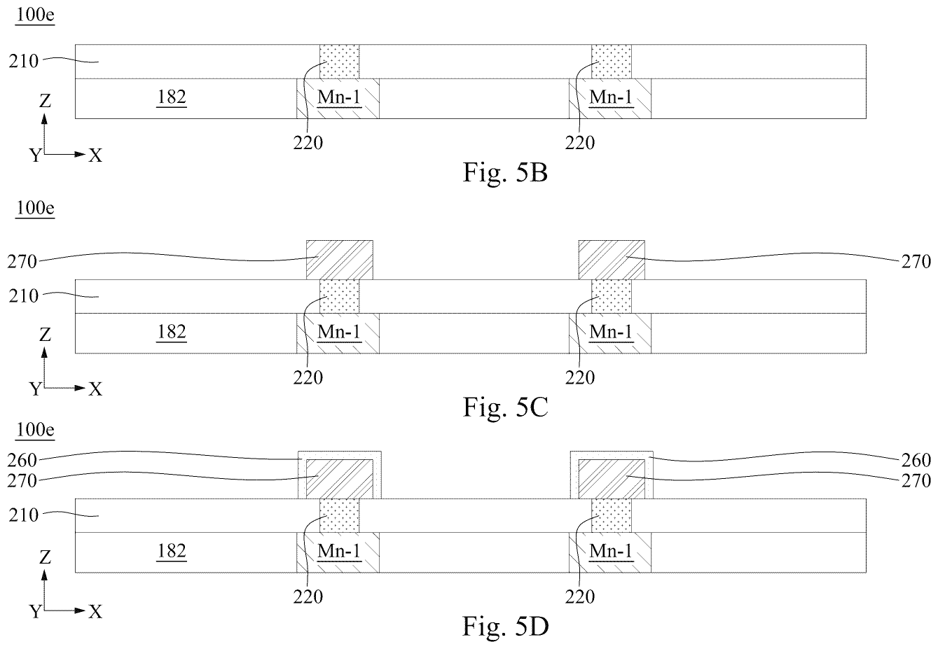

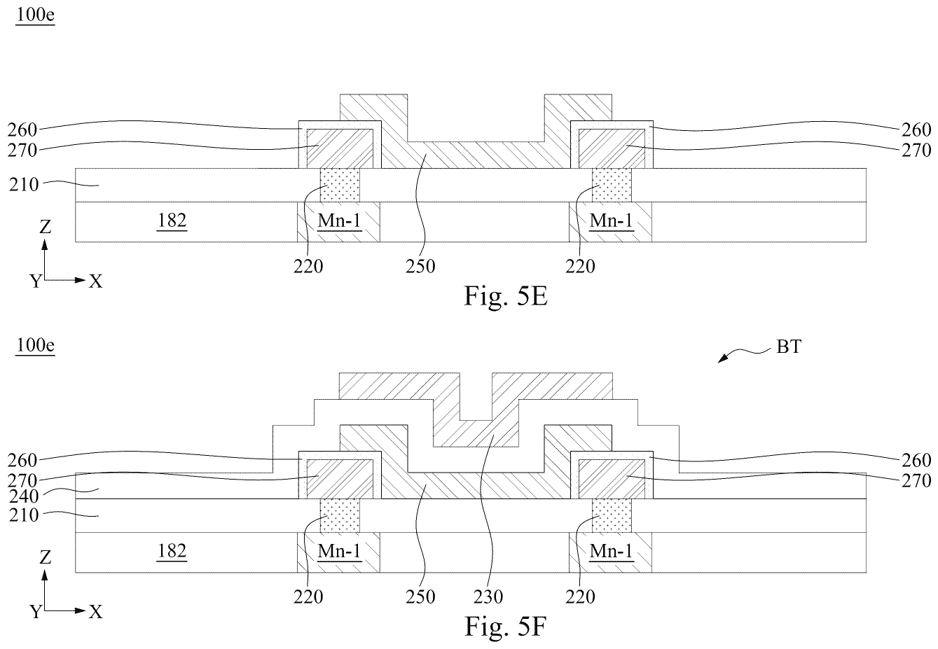

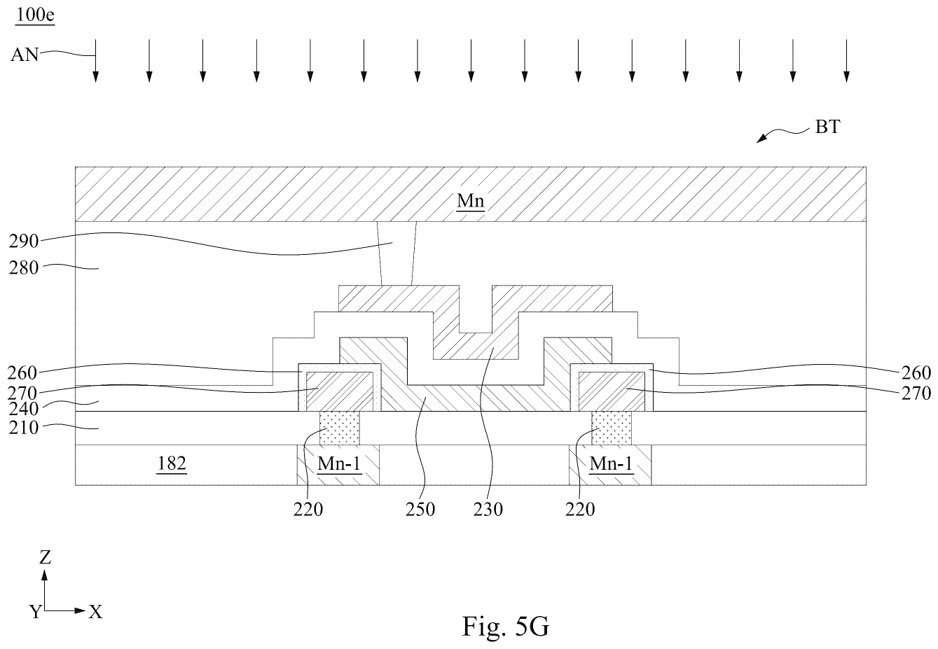

FIGS. 5A-5G illustrate exemplary cross-sectional views of various stages for manufacturing an integrated circuit structure (or a semiconductor device) 100e according to some other embodiments of the present disclosure. It is understood that additional operations can be provided before, during, and after processes shown by FIGS. 5A-5G, and some of the operations described below can be replaced or eliminated, for additional embodiments of the method. The order of the operations/processes may be interchangeable. The same or similar configurations, materials, processes and/or operation as described with FIGS. 1A-1I may be employed in the following embodiments, and the detailed explanation may be omitted.

Reference is made to FIG. 5A. A substrate 110, a transistor FT, and source/drain contacts 170 are provided. A multilevel interconnection structure 180 including multiple interconnect levels is then formed over the substrate 110. The details for forming the substrate 110, the transistor FT, the source/drain contacts 170, and the multilevel interconnection structure 180 are described in FIG. 1A, and, therefore, a description in this regard will not be repeated hereinafter.

In some embodiments, after the formation of the conductive lines Mn−1, a transistor BT (see FIG. 5F) may be formed to be electrically connected to one or some of the conductive lines Mn−1. Reference is made to FIG. 5B. For clarity, the structures under the conductive lines Mn−1 are omitted in FIGS. 5B-5G. The conductive lines Mn−1 are embedded in the IMD layer 182. The top dielectric surface of the IMD layer 182 is shown to be substantially coplanar with the top conductive surfaces of conductive lines Mn−1, within process variations. A dielectric layer 210 is formed over the IMD layer 182. Materials, configurations, dimensions, processes and/or operations regarding the dielectric layer 210 are similar to or the same as the dielectric layer 210 described in FIG. 1B.

Subsequently, conductive vias 220 are formed in the dielectric layer 210. Materials, configurations, dimensions, processes and/or operations regarding the conductive vias 220 are similar to or the same as the conductive vias 220 described in FIG. 1C. The conductive vias 220 are connected to the conductive lines Mn-1, respectively.

Reference is made to FIG. 5C. Source/drain electrodes 270 are formed over the dielectric layer 210. For example, a conductive layer is deposited over the dielectric layer 210 and is then patterned to from the source/drain electrodes 270. Materials, configurations, dimensions, processes and/or operations regarding the source/drain electrodes 270 are similar to or the same as the source/drain electrodes 270 described in FIG. 1H. The source/drain electrodes 270 are connected to the conductive vias 220, respectively. Therefore, the source/drain electrodes 270 are electrically connected to the conductive lines Mn-1 through the conductive vias 220.

Reference is made to FIG. 5D. Conductive interfacial layers 260 are formed to cover the source/drain electrodes 270, respectively. In some embodiments, a conductive layer is deposited over the dielectric layer 210 and the source/drain electrodes 270, and the conductive layer is patterned to form the conductive interfacial layers 260. Materials, configurations, dimensions, processes and/or operations regarding the conductive interfacial layers 260 are similar to or the same as the conductive interfacial layers 260 described in FIGS. 1G and 1H. As shown in FIG. 5D, the conductive interfacial layers 260 are in contact with outer surfaces of the source/drain electrodes 270 to separate the source/drain electrodes 270 from the following formed channel layer 250 (see FIG. 5E).

Reference is made to FIG. 5E. A channel layer 250 is formed over the conductive interfacial layers 260 and the dielectric layer 210. Materials, configurations, dimensions, processes and/or operations regarding the channel layer 250 are similar to or the same as the channel layer 250 described in FIG. 1F. In some embodiments, portions of the conductive interfacial layers 260 are uncovered by the channel layer 250. However, the channel layer 250 is still separated from the source/drain electrodes 270 by the conductive interfacial layers 260.

Reference is made to FIG. 5F. A gate dielectric layer 240 is deposited over the dielectric layer 210 and covers the channel layer 250 and the conductive interfacial layers 260. Materials, configurations, dimensions, processes and/or operations regarding the gate dielectric layer 240 are similar to or the same as the gate dielectric layer 240 described in FIG. 1E. A gate electrode 230 is formed over the gate dielectric layer 240 and the channel layer 250. Materials, configurations, dimensions, processes and/or operations regarding the gate electrode 230 are similar to or the same as the gate electrode 230 described in FIG. 1D. Therefore, the transistor BT is formed.

Reference is made to FIG. 5G. The structure of FIG. 5F undergoes the process shown in FIG. 1I. That is, an IMD layer 280 is formed to cover the structure in FIG. 5F, conductive vias 290 and a conductive line Mn are formed in the IMD layer 280, and an annealing process AN is performed to the device. Materials, configurations, dimensions, processes and/or operations regarding the IMD layer 280 are similar to or the same as the IMD layer 280 described in FIG. 1I, materials, configurations, dimensions, processes and/or operations regarding the conductive vias 290 are similar to or the same as the conductive vias 290 described in FIG. 1I, and materials, configurations, dimensions, processes and/or operations regarding the conductive line Mn are similar to or the same as the conductive lines Mn+1 described in FIG. 1I.

As such, the transistor BT is a p-type thin film transistor (TFT) and includes the gate electrode 230, the gate dielectric layer 240, the channel layer 250, the conductive interfacial layers 260, and the source/drain electrodes 270. The conductive interfacial layers 260 are over the source/drain electrodes 270, respectively, and the channel layer 250 is over the conductive interfacial layers 260 and the dielectric layer 210. The gate dielectric layer 240 covers the channel layer 250, the conductive interfacial layers 260, and the source/drain electrodes 270. The gate electrode 230 is over the gate dielectric layer 240 and the channel layer 250. As shown in FIG. 5G, the channel layer 250 is in contact with a portion of each of the conductive interfacial layer 260, and the gate dielectric layer 240 is in contact with another portion of each of the conductive interfacial layer. In some embodiments, the conductive lines Mn−1 and Mn extend in different directions. For example, the conductive lines Mn−1 extends in the Y direction, and the conductive line Mn extend in the X direction. Further, the conductive line Mn may be thicker than the conductive lines Mn−1 in the Z direction.

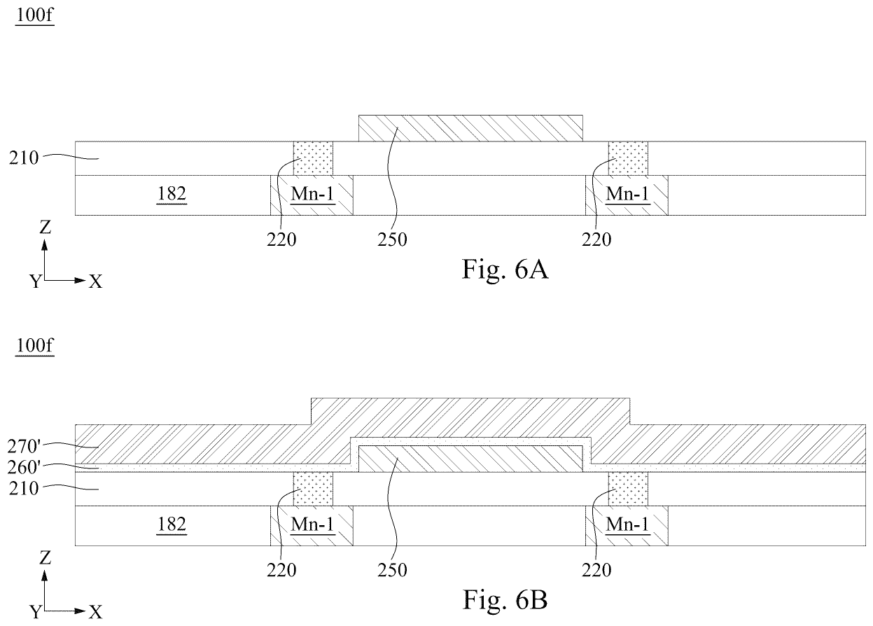

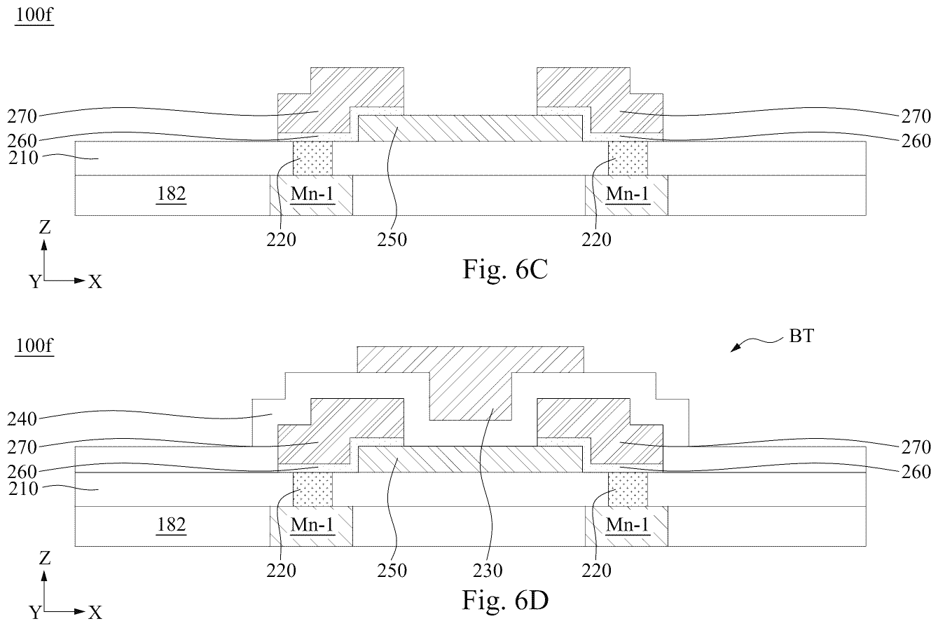

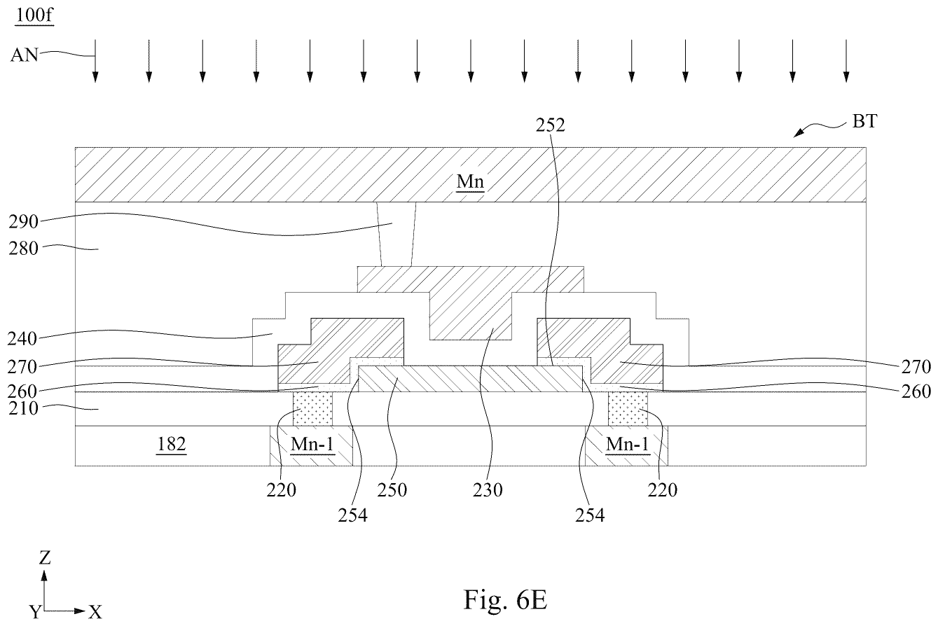

FIGS. 6A-6E illustrate exemplary cross-sectional views of various stages for manufacturing an integrated circuit structure (or a semiconductor device) 100f according to some other embodiments of the present disclosure. It is understood that additional operations can be provided before, during, and after processes shown by FIGS. 6A-6E, and some of the operations described below can be replaced or eliminated, for additional embodiments of the method. The order of the operations/processes may be interchangeable. The same or similar configurations, materials, processes and/or operation as described with FIGS. 5A-5G may be employed in the following embodiments, and the detailed explanation may be omitted.

After the structure as shown in FIG. 5B is formed, a channel layer 250 is formed over the dielectric layer 210 and between the conductive vias 220. Materials, configurations, dimensions, processes and/or operations regarding the channel layer are similar to or the same as the channel layer described in FIG. 1F.

Reference is made to FIG. 6B. A first conductive layer 260′ is deposited over the channel layer 250 and the dielectric layer 210, and a second conductive layer 270′ is deposited over the first conductive layer 260′. Materials, configurations, dimensions, processes and/or operations regarding the first conductive layer 260′ are similar to or the same as the first conductive layer 260′ described in FIG. 1G, and materials, configurations, dimensions, processes and/or operations regarding the second conductive layer 270′ are similar to or the same as the second conductive layer 270′ described in FIG. 1G.

Reference is made to FIG. 6C. The second conductive layer 270′ is patterned to form source/drain electrodes 270 over opposite sides of the channel layer 250. Subsequently, the first conductive layer 260′ is patterned to form conductive interfacial layers 260 between the channel layer 250 and respective source/drain electrodes 270. Therefore, each of the conductive interfacial layers 260 is electrically connected to the corresponding source/drain electrode 270, the channel layer 250, and the corresponding conductive via 220. As such, the source/drain electrodes 270 are electrically connected to the conductive lines Mn-1 through the conductive interfacial layers 260 and the conductive vias 220.

Reference is made to FIG. 6D. A gate dielectric layer 240 is deposited over the dielectric layer 210 and covers the channel layer 250 and the source/drain electrodes 270. Materials, configurations, dimensions, processes and/or operations regarding the gate dielectric layer 240 are similar to or the same as the gate dielectric layer 240 described in FIG. 1E. A gate electrode 230 is formed over the gate dielectric layer 240 and the channel layer 250. Materials, configurations, dimensions, processes and/or operations regarding the gate electrode 230 are similar to or the same as the gate electrode 230 described in FIG. 1D. Therefore, the transistor BT is formed.

Reference is made to FIG. 6E. The structure of FIG. 6D undergoes the process shown in FIG. 1I. That is, an IMD layer 280 is formed to cover the structure in FIG. 6D, conductive vias 290 and a conductive line Mn are formed in the IMD layer 280, and an annealing process AN is performed to the device. Materials, configurations, dimensions, processes and/or operations regarding the IMD layer 280 are similar to or the same as the IMD layer 280 described in FIG. 1I, materials, configurations, dimensions, processes and/or operations regarding the conductive vias 290 are similar to or the same as the conductive vias 290 described in FIG. 1I, and materials, configurations, dimensions, processes and/or operations regarding the conductive line Mn are similar to or the same as the conductive lines Mn+1 described in FIG. 1I.

As such, the transistor BT is a p-type thin film transistor (TFT) and includes the gate electrode 230, the gate dielectric layer 240, the channel layer 250, the conductive interfacial layers 260, and the source/drain electrodes 270. The channel layer 250 is over the dielectric layer 210, and the source/drain electrodes 270 are over and on opposite sides of the channel layer 250. The conductive interfacial layers 260 are partially between the channel layer 250 and the source/drain electrodes 270. The gate dielectric layer 240 covers the channel layer 250, the conductive interfacial layers 260, and the source/drain electrodes 270. The gate electrode 230 is over the gate dielectric layer 240 and the channel layer 250. Further, each of the conductive interfacial layers 260 is in contact with a top surface 252 and a sidewall 254 of the channel layer 250.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the conductive interfacial layer improves the diffusion issue in the p-type channel layer during the annealing process. Further, since the conductive interfacial layer is conductive, the electrical connection between the source/drain electrode and the channel layer is qualified, and the ratio of on current to off current of the transistor is still distinguished after the annealing process. The combinations of the channel layer, the conductive interfacial layers, and the source/drain electrodes have a high thermal stability.

According to some embodiments, a method includes forming a first transistor over a substrate, including forming a gate electrode over the substrate. A gate dielectric layer is formed to cover the gate electrode. A p-type channel layer made of oxide semiconducting materials is formed over the gate dielectric layer. A conductive interfacial layer is formed over the p-type channel layer. The conductive interfacial layer is made of a conductive oxide material, and the conductive interfacial layer and the p-type channel layer comprise a same metal. A first source/drain electrode and a second source/drain electrode are formed on opposite sides of the p-type channel layer. The conductive interfacial layer separates the first source/drain electrode from the p-type channel layer. The first source/drain electrode is made of aluminum-containing materials.

According to some embodiments, a device includes a gate electrode, a gate dielectric layer, a first source/drain electrode, a second source/drain electrode, a p-type channel layer, and a conductive interfacial layer. The gate dielectric layer covers the gate electrode. The first source/drain electrode and the second source/drain electrode are over the gate dielectric layer and are separated from each other. The first source/drain electrode is made of aluminum-containing material. The p-type channel layer is over the gate dielectric layer, between the first source/drain electrode and the second source/drain electrode, and made of an oxide material including a first metal. The conductive interfacial layer separates the first source/drain electrode from the channel layer. The conductive interfacial layer includes the first metal and oxide.

According to some embodiments, a device includes a first aluminum-containing layer, a second aluminum-containing layer, an SnO channel layer, an indium tin oxide layer, a gate dielectric layer, and a gate electrode. The first aluminum-containing layer and the second aluminum-containing layer are separated from each other. The SnO channel layer is between the first aluminum-containing layer and the second aluminum-containing layer. The indium tin oxide layer is between the first aluminum-containing layer and the SnO channel layer. The gate dielectric layer covers the first aluminum-containing layer, the second aluminum-containing layer, and the SnO channel layer. The gate electrode is over the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first transistor over a substrate, comprising:
forming a gate electrode over the substrate;
forming a gate dielectric layer to cover the gate electrode;
forming a p-type channel layer made of oxide semiconducting materials over the gate dielectric layer;
forming a conductive interfacial layer over the p-type channel layer, wherein the conductive interfacial layer is made of a conductive oxide material, and the conductive interfacial layer and the p-type channel layer comprise a same metal; and
forming a first source/drain electrode and a second source/drain electrode on opposite sides of the p-type channel layer, wherein the conductive interfacial layer separates the first source/drain electrode from the p-type channel layer, and the first source/drain electrode is made of aluminum-containing materials.

2. The method of claim 1, wherein the p-type channel layer is made of SnO.

3. The method of claim 1, wherein the conductive interfacial layer is substantially free of aluminum.

4. The method of claim 1, wherein an aluminum atomic percentage of the first source/drain electrode is greater than about 50%.

5. The method of claim 1, further comprising performing an annealing process to the first transistor.

6. The method of claim 5, wherein after performing the annealing process, a ratio of on current to off current of the first transistor is in a range of about 10² and about 10¹⁰.

7. The method of claim 1, further comprising forming a second transistor over the substrate prior to forming the first transistor, wherein the first transistor is formed over the second transistor.

8. The method of claim 7, wherein the second transistor is a FinFET, a planar FET, a horizontal gate-all-around (HGAA) FET, or a vertical gate-all-around (VGAA) FET.

9. The method of claim 1, further comprising:
forming a first conductive line over the substrate prior to forming the first transistor, wherein the first transistor is formed over and electrically connected to the first conductive line; and
forming a second conductive line over and electrically connected to the first transistor, wherein the first conductive line and the second conductive line extend in different directions.

10. The method of claim 9, wherein the second conductive line is thicker than the first conductive line.

11. A device comprising:
a gate electrode;
a gate dielectric layer covering the gate electrode;
a first source/drain electrode and a second source/drain electrode over the gate dielectric layer and separated from each other, wherein the first source/drain electrode is made of aluminum-containing material;
a p-type channel layer over the gate dielectric layer, between the first source/drain electrode and the second source/drain electrode, and made of an oxide material comprising a first metal; and
a conductive interfacial layer separating the first source/drain electrode from the p-type channel layer, wherein the conductive interfacial layer comprises the first metal and oxide.

12. The device of claim 11, wherein an atomic percentage of the first metal in the p-type channel layer is higher than an atomic percentage of the first metal in the conductive interfacial layer.

13. The device of claim 11, wherein the conductive interfacial layer further comprises a second metal, wherein an atomic percentage of the second metal in the conductive interfacial layer is higher than an atomic percentage of the first metal in the conductive interfacial layer.

14. The device of claim 11, wherein the first source/drain electrode is made of pure aluminum or aluminum alloy.

15. The device of claim 11, wherein the conductive interfacial layer is over the first source/drain electrode, and the p-type channel layer partially covers the conductive interfacial layer.

16. A device comprising:
a first aluminum-containing layer and a second aluminum-containing layer separated from each other;
an SnO channel layer between the first aluminum-containing layer and the second aluminum-containing layer;
an indium tin oxide layer between the first aluminum-containing layer and the SnO channel layer;
a gate dielectric layer covering the first aluminum-containing layer, the second aluminum-containing layer, and the SnO channel layer; and
a gate electrode over the gate dielectric layer.

17. The device of claim 16, wherein the SnO channel layer is separated from the first aluminum-containing layer by the indium tin oxide layer.

18. The device of claim 16, wherein the SnO channel layer is in contact with a portion of the indium tin oxide layer, and the gate dielectric layer is in contact with another portion of the indium tin oxide layer.

19. The device of claim 16, wherein the indium tin oxide layer is in contact with a top surface and a sidewall of the SnO channel layer.

20. The device of claim 16, wherein a thickness of the SnO channel layer is greater than a thickness of the indium tin oxide layer.
